(19) United States
(12) Patent Application Publication
(10) Pub. No.: US 2010/0207691 A1
(43) Pub. Date: Aug. 19, 2010

(54) PHASE MISMATCH COMPENSATION DEVICE

(75) Inventor: Seyeob KIM, Gyeonggi-do (KR)

Correspondence Address: FOLEY AND LARDNER LLP;SUITE 500, 3000 K STREET NW, WASHINGTON, DC, 20007, US

(73) Assignee: INTEGRANT TECHNOLOGIES INC.

(21) Appl. No.: 12/388,181

(22) Filed: Feb. 18, 2009

(51) Int. Cl. H03F 3/45

(52) U.S. Cl. 330/69

(57) ABSTRACT

A phase mismatch compensation device comprises a first low pass filter unit, a second low pass filter unit and a phase compensation unit. The first low pass filter unit comprises a first input unit transferring the I-channel analog input signal to an input terminal of a first OP-amp, and the first self-feedback unit transferring the I-channel output signal to the input terminal of the first OP-amp. The second low pass filter unit comprises the second input unit transferring the Q-channel analog input signal to an input terminal of a second OP-amp, and a second self-feedback unit transferring the Q-channel output signal to the input terminal of the second OP-amp. The phase compensation unit comprises a first compensation unit transferring the Q-channel analog input signal to the input terminal of the first OP-amp, and a second compensation unit transferring the I-channel analog input signal to the input terminal of the second OP-amp.

### BACKGROUND

1. Field

The present invention relates to a phase mismatch compensation device.

2. Description of the Related Art

FIG. 1 is a view illustrating the structure of a Bluetooth receiver as one example of a low-intermediate frequency (IF) receiver. At the radio frequency (RF) front end, an RF signal is amplified and down-converted to an IF signal. Then, channel selection is performed in an active complex filter. Subsequently, the IF signal is amplitude limited by an amplitude limiter and then demodulated by a frequency shift keying (GFSK) demodulator.

Here, it is preferable that in-phase channel (I-channel) and quadrature-phase channel (Q-channel) signals have an exact phase difference of 90 degrees for the purpose of exact restoration of a signal. However, typically, the phase difference between the I-channel and Q-channel signals is not exactly 90 degrees due to the implementation state and external environment of a circuit. Therefore, a device that compensates for the phase difference between the I-channel and Q-channel signals is frequently used in a digital area. However, if the phase difference between the I-channel and Q-channel signals is large when the phase difference compensation is performed in the digital area, it is difficult to perform the phase difference compensation. Since complicated digital processing is required in the phase difference compensation, its processing speed is slow. Further, a pilot signal with a long period is required in estimating the exact phase difference, and therefore, overheads are increased.

In a related art analog area, techniques for adding an I/Q phase mismatch compensation circuit to a receiver performance of a zero-IF or low-FI receiver used to design a maximally simplified RF circuit for a reliable communication system.

### SUMMARY

In one aspect, a phase mismatch compensation device filtering in-phase channel and quadrature-phase channel analog input signals and outputting I-channel and Q-channel output signals, the phase mismatch compensation device comprises a first low pass filter unit comprising a first OP-amp, a first input unit and a first self-feedback unit, the first input unit transferring the I-channel analog input signal to an input terminal of the first OP-amp, and the first self-feedback unit transferring the I-channel output signal to the input terminal of the first OP-amp; a second low pass filter unit comprising a second OP-amp, a second input unit and a second self-feedback unit, the second input unit transferring the Q-channel analog input signal to an input terminal of the second OP-amp, and the second self-feedback unit transferring the Q-channel output signal to the input terminal of the second OP-amp; and a phase compensation unit comprising a first compensation unit and a second compensation unit, the first compensation unit transferring the Q-channel analog input signal to the input terminal of the first OP-amp, and the second compensation unit transferring the I-channel analog input signal to the input terminal of the second OP-amp.

In another aspect, a phase mismatch compensation device filtering I-channel and Q-channel analog input signals and outputting I-channel and Q-channel output signals, the complex bandpass filter comprises an I-channel phase conversion unit changing the phase of the I-channel output signal using the I-channel and Q-channel analog input signals; a Q-channel phase conversion unit changing the phase of the Q-channel output signal using the I-channel and Q-channel analog input signals; and a complex filter unit performing filtering.

In still another aspect, a phase mismatch compensation device comprises a first amplifier unit amplifying in-phase channel analog input signals with a gain and outputting I-channel output signal, and comprising a first OP-amp, a first input unit and a first self-feedback unit, the first input unit transferring the I-channel analog input signal to an input terminal of the first OP-amp, and the first self-feedback unit transferring the I-channel output signal to the input terminal of the first OP-amp; a second amplifier unit amplifying quadrature-phase channel analog input signals with a gain and outputting Q-channel output signal, and comprising a second OP-amp, a second input unit and a second self-feedback unit, the second input unit transferring the Q-channel analog input signal to an input terminal of the second OP-amp, and the second self-feedback unit transferring the Q-channel output signal to the input terminal of the second OP-amp; and a phase compensation unit comprising a first compensation unit and a second compensation unit, the first compensation unit transferring the Q-channel analog input signal to the input terminal of the first OP-amp, and the second compensation unit transferring the I-channel analog input signal to the input terminal of the second OP-amp.

### BRIEF DESCRIPTION OF THE DRAWINGS

The accompany drawings, which are included to provide a further understanding of the invention and are incorporated on and constitute a part of this specification, illustrate embodiments of the invention and together with the description serve to explain the principles of the invention. In the drawings:

FIG. 1 is a view illustrating the structure of a Bluetooth receiver as one example of a low-intermediate frequency (IF) receiver;

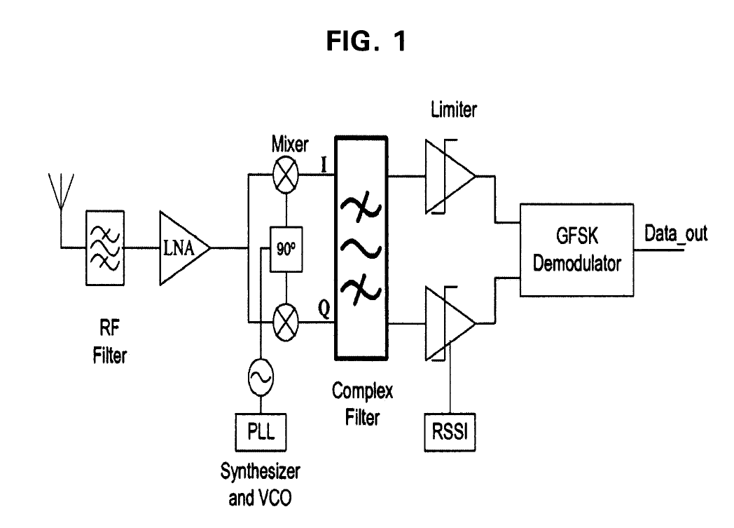

FIG. 2 is a block diagram of a phase mismatch compensation device applied to a complex bandpass filter according to an embodiment of the present invention;

FIG. 3 is a view illustrating transfer functions of a low pass filter and a complex bandpass filter;

FIG. 4 is a view illustrating an implementation of transfer function Hbp(jw) of the complex bandpass filter;

FIG. 5 is a circuit diagram of a complex bandpass filter implemented using active-RC;

FIG. 6 illustrates a phase mismatch compensation device applied to a complex bandpass filter according to an embodiment of the present invention; and

FIG. 7 illustrates a phase mismatch compensation device applied to a complex bandpass filter according to another embodiment of the present invention.

FIG. 8 illustrates a phase mismatch compensation device according to still another embodiment of the present invention.

FIG. 9 illustrates a phase mismatch compensation device according to still another embodiment of the present invention.

### DETAILED DESCRIPTION OF EMBODIMENTS

Reference will now be made in detail embodiments of the invention examples of which are illustrated in the accompanying drawings.

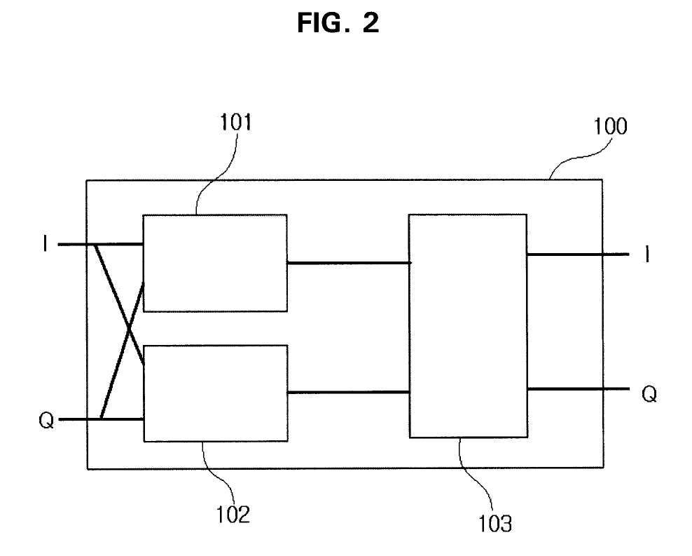

FIG. 2 is a block diagram of a phase mismatch compensation device applied to a complex bandpass filter according to an embodiment of the present invention. Referring to FIG. 2, the phase mismatch compensation device 100 according to the embodiment of the present invention filters in-phase channel (I-channel) and quadrature-phase channel (Q-channel) analog input signals and then outputs I-channel and Q-channel output signals. Here, phase mismatch compensation device 100 comprises an I-channel phase conversion unit 101 converting the phase of an I-channel output signal using I-channel and Q-channel analog input signals; a Q-channel phase conversion unit 102 converting the phase of a Q-channel output signal using I-channel and Q-channel analog input signals; and a complex filter unit 103 performing filtering. In FIG. 2, a signal is processed by the I-channel and Q-channel phase conversion units 101 and 102, and the processed signal is then processed by the complex filter unit 103. However, the present invention is not limited to such a processing order.

For a further understanding of the present invention, a complex bandpass filter will be first described. The complex bandpass filter is a filter that has different responses with respect to positive and negative frequencies. The complex bandpass filter is also referred to as a Hilbert filter. A signal inputted to the complex filter are a polyphase signal. Here, the polyphase signal refers to vectors of individual signals. Typically, an input of the complex bandpass filter is a polyphase signal of four individual signals.

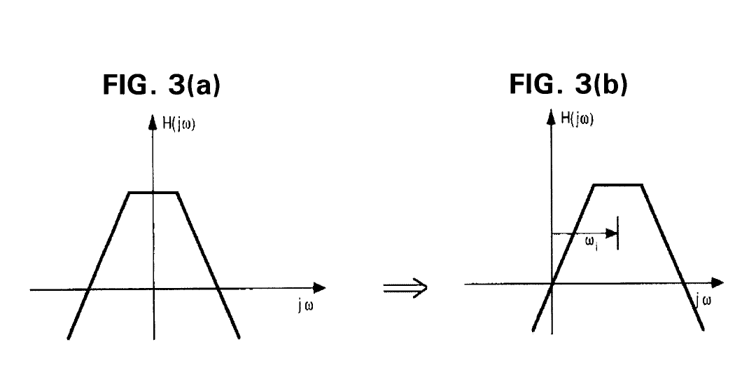

FIG. 3 is a view illustrating transfer functions of a low pass filter and a complex bandpass filter. The transfer function of the complex bandpass filter is obtained by frequency-converting the low pass filter as expressed in the following expression.

H_{bp}(jω)=Hₗₚ(jω−jω_{c}) (1)

The transfer functions of the low pass filter and the complex bandpass filter are respectively expressed as follows.

$${H}_{lp} ( j ω ) = \frac{1}{1 + j ω / {ω}_{o}} \\ \begin{matrix}{H}_{bp} ( j ω ) = \frac{1}{1 - j {ω}_{c} / {ω}_{o} + j ω / {ω}_{o}} \\ = \frac{1}{1 - 2 j Q + j ω / {ω}_{o}}\end{matrix} \qquad ( 2 )$$

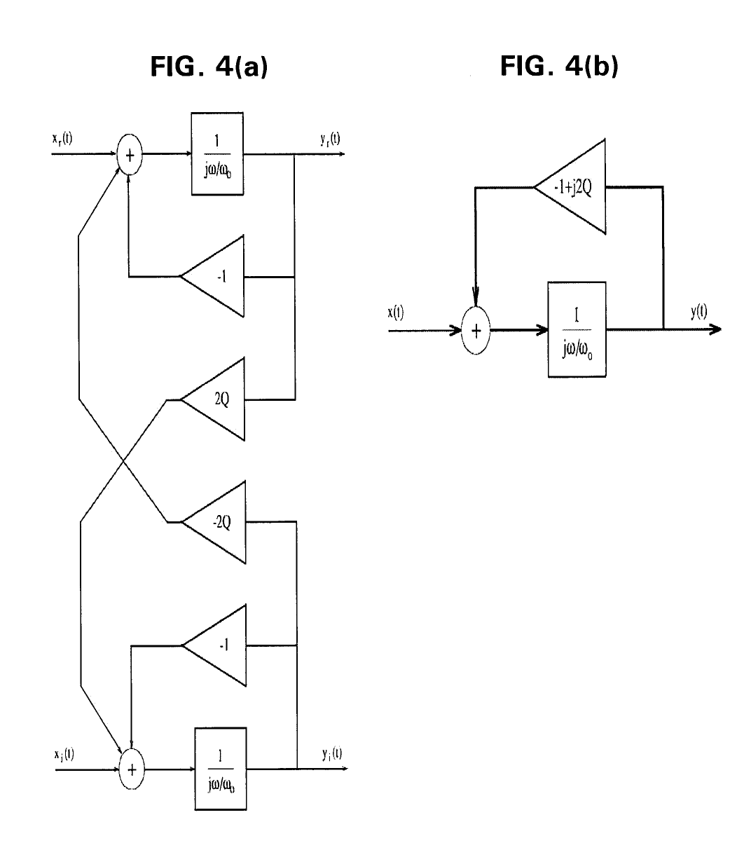

FIG. 4 illustrates an implementation of the transfer function Hbp(jw) of the complex bandpass filter. (a) of FIG. 4 illustrates a configuration obtained by directly synthesizing the transfer function Hbp(jw), and (b) of FIG. 4 illustrates a configuration obtained by simplifying the configuration illustrated in (a) of FIG. 4.

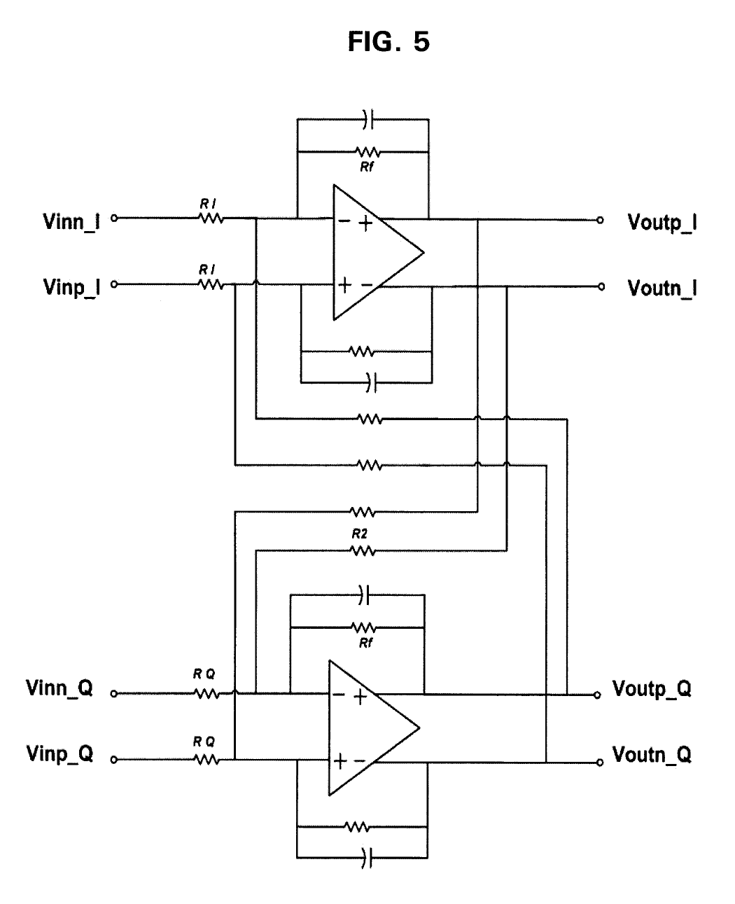

Such a complex bandpass filter may be implemented using active-RC, OTA-C, MOSFET-C, switched capacitor and the like. FIG. 5 is a circuit diagram of a complex bandpass filter implemented using the active-RC.

A phase mismatch compensation device according to an embodiment of this invention can be applied to various devices such like the complex bandpass filter.

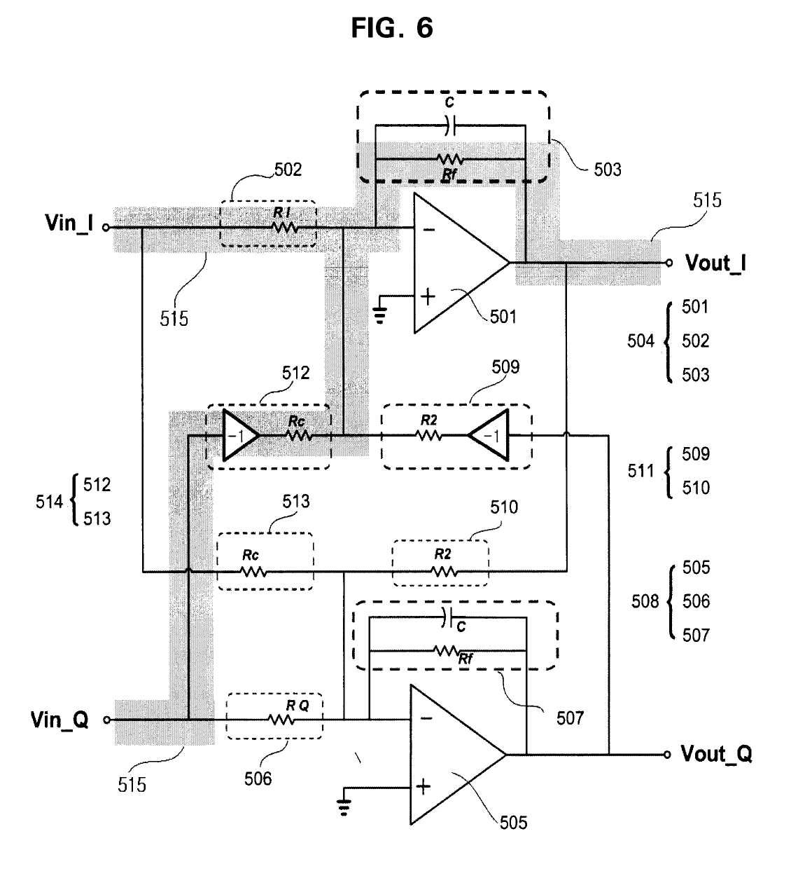

FIG. 6 illustrates a phase mismatch compensation device applied to the complex bandpass filter according to an embodiment of the present invention. For convenience of illustration, the complex bandpass filter illustrated in FIG. 5 is simplified as a single-input single-output circuit.

The phase mismatch compensation device according to the embodiment of the present invention filters I-channel and Q-channel analog input signals Vin_I and Vin_Q and then outputs I-channel and Q-channel output signals Vout_I and Vout_Q. The phase mismatch compensation device comprises a first low pass filter unit 504, a second low pass filter unit 508, a polar conversion unit 511 and a phase compensation unit 514.

The first low pass filter unit 504 comprises a first OP-amp 501, a first input unit 502 transferring an I-channel analog input signal to an input terminal of the first OP-amp 501, and a first self-feedback unit 503 transferring an I-channel output signal to the input terminal of the first OP-amp 501.

The second low pass filter unit 508 comprises a second OP-amp 505, a second input unit 506 transferring a Q-channel analog input signal to an input terminal of the second OP-amp 505, and a second self-feedback unit 507 transferring a Q-channel output signal to the input terminal of the second OP-amp 505.

The polar conversion unit 511 comprises a first cross-feedback unit 509 transferring a Q-channel output signal to the input terminal of the first OP-amp 510, and a second cross-feedback unit 510 transferring an I-channel output signal to the input terminal of the second OP-amp 505.

The phase compensation unit 514 comprises a first compensation unit 512 transferring a Q-channel analog input signal to the input terminal of the first OP-amp 501, and a second compensation unit 513 transferring an I-channel analog input signal to the input terminal of the second OP-amp 505.

In the embodiment, the first input unit 502 comprises an input resistor RI and a conductive wire through which signals are transferred, and the second input unit 506 comprises an input resistor RQ and a conductive wire through which signals are transferred. The first cross-feedback unit 509 comprises a resistor R2 and a conductive wire through which signals are transferred, and the second cross-feedback unit 510 comprises a resistor R2 and a conductive wire through which signals are transferred.

The first cross-feedback unit 509 comprises an inverting amplifier that inverts the sign of a Q-channel output signal and transfers the Q-channel output signal with the inverted sign to the input terminal of the first OP-amp 501. In a fully differential amplification structure which will be described later, inverting or non-inverting input/output terminals of an OP-amp are connected to cross each other, and therefore, an inverting amplifier may be omitted. Here, impedance elements predetermined values may be used as the respective resistors, respectively.

In the embodiment, the first self-feedback unit 503 comprises a resistor Rf and a capacitor C, which are connected in parallel with each other, and a conductive wire through which signals are transferred. The second self-feedback unit 507 comprises a resistor Rf and a capacitor C, which are connected in parallel with each other, and a conductive wire through which signals are transferred. The first compensation unit 512 comprises an inverting amplifier that inverts a Q-channel analog input signal and transfers the inverted Q-channel analog input signal to the input terminal of the first OP-amp 501.

In the fully differential amplification structure which will be described later, inverting or non-inverting input/output terminals of an OP-amp are connected to cross each other, and therefore, an inverting amplifier may be omitted. Here, impedance elements predetermined values may be used as the respective resistors, respectively.

In the embodiment, the first compensation unit 512 comprises a variable resistor RC and a conductive wire through which signals are transferred. The second compensation unit 513 comprises a variable resistor RC and a conductive wire through which signals are transferred. Here, variable impedance elements may be used as the respective variable resistors.

Referring back to FIG. 6, the connection of the elements included in each of the components will be described. First, an I-channel signal path will be described. One end of the input resistor RI is connected to an inverting input terminal of the OP-amp 501, and the other end of the input resistor RI is connected to an I-channel input terminal.

One end of the compensation resistor RC is connected to the inverting input terminal of the OP-amp 501, and the other end of the compensation resistor RC is connected to a Q-channel input terminal. An output terminal of the OP-amp 501 serves as an I-channel output terminal.

An output signal of the OP-amp 501 is fed back to the inverting input terminal of the OP-amp 501 by the resistor RF and the capacitor C, which are connected in parallel with each other. A Q-channel output signal is fed back to the inverting input terminal of the OP-amp 501 by the resistor R2.

Next, a Q-channel signal path will be described. One end of the input resistor RQ is connected to an inverting input terminal of the OP-amp 505, and the other end of the input resistor RQ is connected to the Q-channel input terminal. One end of the compensation resistor RC is connected to the inverting input terminal of the OP-amp 505, and the other end of the compensation resistor RC is connected to the I-channel input terminal. An output terminal of the OP-amp 505 serves as a Q-channel output terminal.

An output signal of the OP-amp 505 is fed back to the inverting input terminal of the OP-amp 505 by the resistor Rf and the capacitor C, which are connected in parallel with each other. An I-channel output signal is fed back to the inverting input terminal of the OP-amp 505 by the resistor R2.

In the phase mismatch compensation device according to the embodiment of the present invention, the resistance of the compensation resistor RC is adjusted, thereby compensating for the phase different between the I-channel and Q-channel output signals. In the circuit illustrated in FIG. 6, a phase mismatch compensation operation of the complex bandpass filter according to the embodiment of the present invention will be described, considering only a route 515 indicated by shadow and the OP-amp 501.

A relation between analog input signals Vin_I and Vin_Q and an output signal Vout_I in the complex bandpass filter is satisfied as follows.

$$Vout\_I = - \frac{Rf}{RI} Vin\_I + \frac{Rf}{RC} Vin\_Q \qquad ( 3 )$$

Here, the I-channel and Q-channel analog input signals Vin_I and Vout_Q are analog signals substantially having a phase difference of 90 degrees. For example, if it is assumed that Vin_I=cos(wt) and Vin Q=sin(wt), the I-channel output signal is expressed as follows.

$$Vout\_I = - \frac{Rf}{RI} cos ( ω t ) + \frac{Rf}{RC} sin ( ω t ) \qquad ( 4 )$$

Here, if values of RI and RC are designed so that

$$\frac{Rf}{RI} = cos φ ,$$

$$\frac{Rf}{RC} = sin φ ,$$

the I-channel output signal is expressed as follows.

Vout_{—}I=−cos φ cos(ωₜ)+sin φ sin(ωt)=−cos(Ωt+φ) (5)

Accordingly, if resistances of the compensation resistor RC and the input resistor RI are changed so that

$$RC = \frac{RI}{tan φ} ,$$

the phase of the I-channel output signal can be adjusted by 180°+φ. As described above, when the I-channel and Q-channel analog input signals have a phase difference of 90 degrees, the phase of the output signal is changed. The phase mismatch compensation device satisfying formulas (3), (4) and (5) expressed above can be applied to various devices as well as the complex bandpass filter.

For simplification of illustration, the phase mismatch compensation device according to the embodiment of the present invention has been described considering only the elements and the OP-amp 501, which are included in the route 515. However, it will be understood that the phase mismatch compensation operation according to the embodiment of the present invention can be implemented even considering other elements.

In the same manner, the phase of the Q-channel output signal can be changed by adjusting resistance of the compensation resistor RC. The adjustment of the compensation resistor RC may be performed using a variable resistor or using a method in which compensation resistors RI and RC are previously integrated, and desired resistance is obtained by applying a gate voltage depending on conditions.

Alternatively, the adjustment of the compensation resistor RC may be performed using a method in which compensation resistors RI and RC with various resistances are previously integrated, and an appropriate compensation resistor is selected automatically or by a user depending on a signal receiving state caused by the I/Q phase mismatch.

As described above, I/Q phase mismatch compensation is performed in the analog area of a low-IF system. Accordingly, although the phase difference between I-channel and Q-channel signals is large, phase compensation can be easily performed, and time and cost required in the phase compensation can be saved.

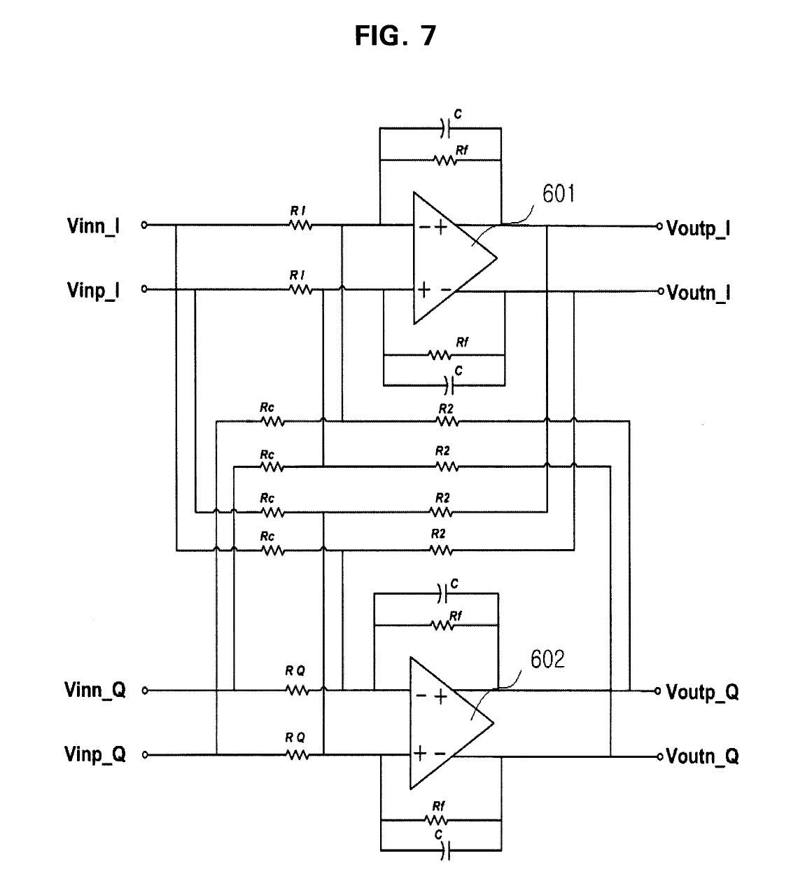

FIG. 7 illustrates a phase mismatch compensation device according to another embodiment of the present invention.

In the embodiment of FIG. 7, the OP-Amps 501 and 505 of the complex bandpass filter illustrated in FIG. 6 are replaced by fully differential OP-amps 601 and 605, respectively. In the complex bandpass filter illustrated in FIG. 6, the I-channel input/out signals Vin_I and Vout_I and the Q-channel input/output signals Vin_Q and Vout_Q are transferred through single paths. However, the fully differential OP-amps 601 and 605 of the complex bandpass filter illustrated in FIG. 7 receive differential signals Vinn_I, Vinp_I, Vinn_Q and Vinp_Q, each of which has a phase difference of 180 degrees, and amplify the amplitude difference between analog input signals.

The I-channel analog input signal Vin_I comprises negative and positive I-channel analog input signals Vinn_I and Vinp_I which have a phase difference of 180 degrees. The I-channel output signal Vout_I comprises negative and positive I-channel output signals Voutn_I and Voutp_I which have a phase difference of 180 degrees.

The Q-channel analog input signal Vin_Q comprises negative and positive Q-channel analog input signals Vinn_Q and Vinp_Q which have a phase difference of 180 degrees. The Q-channel output signal Vout_Q comprises negative and positive Q-channel output signals Voutn_Q and Voutp_Q.

It will be readily understood by those skilled in the art that the fully differential structure of FIG. 7 can be derived from the circuit illustrate in FIG. 6. Therefore, the detailed description of an operation of the complex bandpass filter illustrated in FIG. 7 will be replaced by the description of the complex bandpass filter illustrated in FIG. 6.

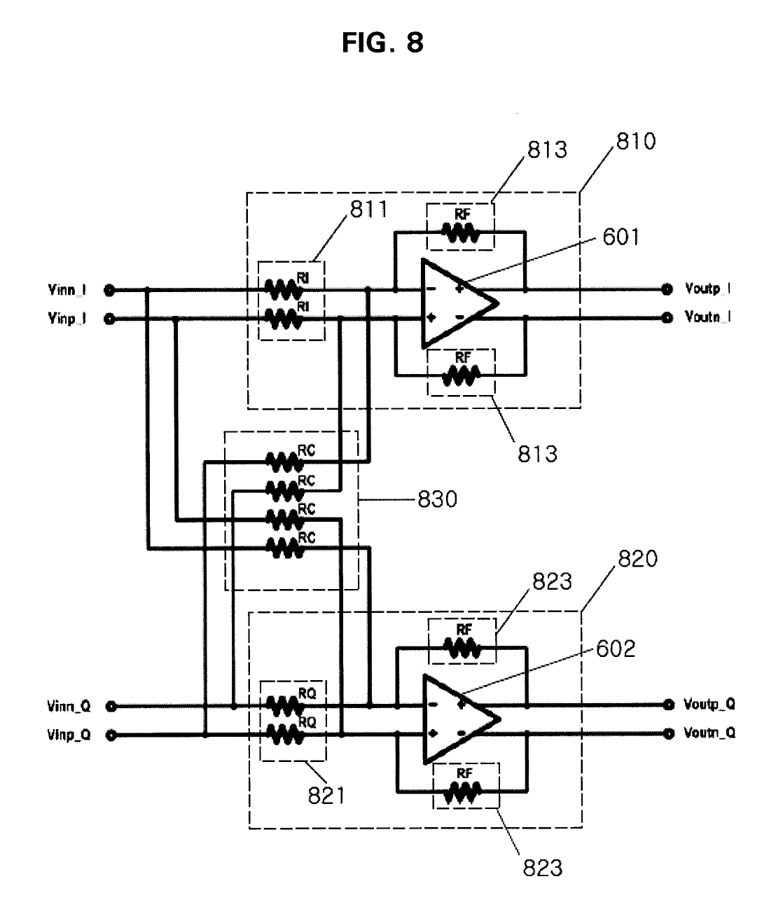

As illustrated in FIG. 8, the phase mismatch compensation device performs an inverting amplification operation, and does not comprise a resistor R2 and a capacitor C of FIG. 7. The phase mismatch compensation device comprises a first amplifier unit 810, a second amplifier unit 820 and a phase compensation unit 830. The fully differential OP-amps 601 and 602 of FIG. 8 are explained above, and the explanation of the fully differential OP-amps 601 and 602 of FIG. 8 is omitted.

The phase difference of I channel output signals Voutp_I and Voutn_I and I channel output signals Vinn_I and Vinp_I is 180 degrees, and the phase difference of Q channel output signals Voutp_Q and Voutn_Q, and Q channel output signals Vinn_Q and Vinp_Q is 180 degrees.

The first amplifier unit 810 comprises a first OP-amp 601, a first input unit 811 and a first self-feedback unit 813. The first input unit 811 transfers the I-channel analog input signal Vinn_I and Vinp_I to an input terminal of the first OP-amp 601. The first self-feedback unit 813 transfers the I-channel output signal Voutp_j and Voutn_I to the input terminal of the first OP-amp 601.

The second amplifier unit 820 comprises a second OP-amp 602, a second input unit 821 and a second self-feedback unit 823. The second input unit 821 transfers the Q-channel analog input signal Vinn_Q and Vinp_Q to an input terminal of the second OP-amp 602. The second self-feedback unit 823 transfers the Q-channel output signal Voutp_Q and Voutn_Q to the input terminal of the second OP-amp 602.

The phase compensation unit 830 comprises a first compensation unit and a second compensation unit. The first compensation unit transfers the Q-channel analog input signal Vinn_Q and Vinp_Q to the input terminal of the first OP-amp 601, and the second compensation unit transfers the I-channel analog input signal Vinn-I and Vinp_I to the input terminal of the second OP-amp 602.

The first amplifier unit 810 performs an operation satisfying the following formula (6).

$$\begin{matrix}Voutp\_I = - \frac{Rf}{RI} Vinn\_I & ( 6 ) \\ Voutn\_I = - \frac{Rf}{RI} Vinp\_I & ( 6 )\end{matrix}$$

The second amplifier unit 820 performs an operation satisfying the following formula (7).

$$\begin{matrix}Voutp\_Q = - \frac{Rf}{RQ} Vinn\_Q & ( 7 ) \\ Voutn\_Q = - \frac{Rf}{RQ} Vinp\_Q & ( 7 )\end{matrix}$$

In formulas (6) and (7), −(Rf/RI) is a gain of the first amplifier units 810 and −(Rf/RQ) is a gain of the second amplifier units 820.

Since the resistor RC also forms the route 505 of FIG. 6, the phase mismatch compensation device satisfies the formulas (3), (4) and (5). Accordingly, the phases of output signals are varied if resistance of the resistor RC is adjusted.

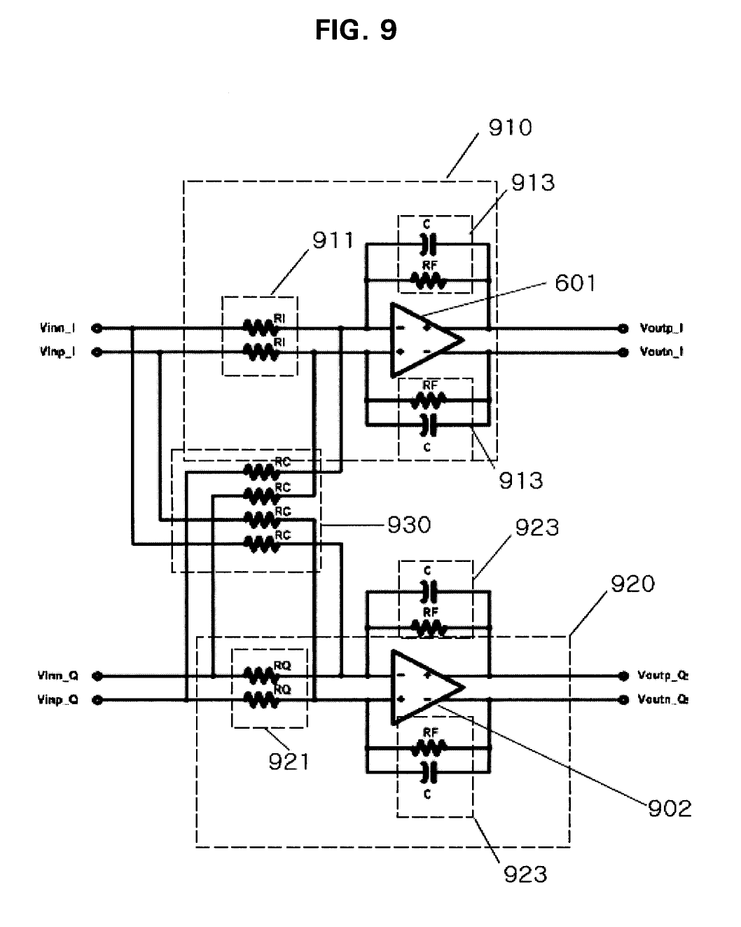

As illustrated in FIG. 9, the phase mismatch compensation device has first order filter structure, and does not the resistor R2 of FIG. 7. The phase mismatch compensation device of FIG. 9 comprises a first low pass filter unit 910, a second low pass filter unit 920 and a phase compensation unit 930. The fully differential OP-amps 601 and 602 of FIG. 9 are explained above, and the explanation of the fully differential OP-amps 601 and 602 of FIG. 9 is omitted.

The first low pass filter unit 910 comprises a first OP-amp 601, a first input unit 911 and a first self-feedback unit 913. The first input unit 911 transfers the I-channel analog input signal Vinn_I and Vinp_I to an input terminal of the first OP-amp 601. The first self-feedback unit 913 transfers the I-channel output signal Voutp_I and Voutn_I to the input terminal of the first OP-amp 601.

The second low pass filter unit 920 comprises a second OP-amp 602, a second input unit 921 and a second self-feedback unit 923. The second input unit 921 transfers the Q-channel analog input signal Vinn_Q and Vinp_Q to an input terminal of the second OP-amp 602. The second self-feedback unit 923 transfers the Q-channel output signal Voutp_Q and Voutn_Q to the input terminal of the second OP-amp 602.

The phase compensation unit 830 comprises a first compensation unit and a second compensation unit. The first compensation unit transfers the Q-channel analog input signal Vinn_Q and Vinp_Q to the input terminal of the first OP-amp 601, and the second compensation unit transfers the I-channel analog input signal Vinn_I and Vinp_I to the input terminal of the second OP-amp 602.

The resistor RF and the capacitor C of the first and second low pass filter units 910 and 920 forms impedance which is expressed as follows.

$$\frac{RF}{1 + sCRF} \qquad ( 8 )$$

Accordingly, a magnitude of the output signal of the phase mismatch compensation device is expressed as follows.

$$Voutp\_I = - \frac{( \frac{RF}{1 + sCRF} )}{RI} Vinn\_I \qquad ( 9 )$$

s of the formula (9) means j2πf. When frequency is 0, the formula (9) becomes the formula (6), and as the frequency f increases, Voutp_I decreases. Accordingly, the phase mismatch compensation device performs low-pass filtering operation.

Since the resistor RC also forms the route 505 of FIG. 6, the phase mismatch compensation device satisfies the formulas (3), (4) and (5). Accordingly, the phases of output signals are varied if resistance of the resistor RC is adjusted.

The foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art.

What is claimed is:

1. A phase mismatch compensation device filtering in-phase channel and quadrature-phase channel analog input signals and outputting I-channel and Q-channel output signals, the phase mismatch compensation device comprising:
a first low pass filter unit comprising a first OP-amp, a first input unit and a first self-feedback unit, the first input unit transferring the I-channel analog input signal to an input terminal of the first OP-amp, and the first self-feedback unit transferring the I-channel output signal to the input terminal of the first OP-amp;
a second low pass filter unit comprising a second OP-amp, a second input unit and a second self-feedback unit, the second input unit transferring the Q-channel analog input signal to an input terminal of the second OP-amp, and the second self-feedback unit transferring the Q-channel output signal to the input terminal of the second OP-amp; and
a phase compensation unit comprising a first compensation unit and a second compensation unit, the first compensation unit transferring the Q-channel analog input signal to the input terminal of the first OP-amp, and the second compensation unit transferring the I-channel analog input signal to the input terminal of the second OP-amp.

2. The phase mismatch compensation device according to claim 1, further comprises a polar conversion unit comprising a first cross-feedback unit and a second cross-feedback unit, the first cross-feedback unit transferring the Q-channel output signal to the input terminal of the first OP-amp, and the second cross-feedback unit transferring the I-channel output signal to the input terminal of the second OP-amp.

3. The phase mismatch compensation device according to claim 1, wherein:
each of the first and second input units and the first and second cross-feedback units comprises a resistor with a predetermined resistance;
each of the first and second self-feedback units comprises a resistor with a predetermined resistance and a capacitor; and
each of the first and second compensation units comprises a variable resistor.

4. The phase mismatch compensation device according to claim 1, wherein:
each of the first and second input units and the first and second cross-feedback units comprises an impedance element with a predetermined impedance;
each of the first and second self-feedback units comprises an impedance element with a predetermined impedance; and
each of the first and second compensation units comprises a variable impedance element.

5. The phase mismatch compensation device according to claim 3, wherein:
the first cross-feedback unit comprises an inverting amplifier converting the phase of the Q-channel output signal into 180 degrees; and
the first compensation unit comprises an inverting amplifier converting the phase of the Q-channel analog input signal into 180 degrees.

6. The phase mismatch compensation device according to claim 4, wherein:
the first cross-feedback unit comprises an inverting amplifier converting the phase of the Q-channel output signal into 180 degrees; and
the first compensation unit comprises an inverting amplifier converting the phase of the Q-channel analog input signal into 180 degrees.

7. The phase mismatch compensation device according to claim 1, wherein:
each of the I-channel input/output signals and the Q-channel input/output signals comprises fully differential signals having a phase difference of 180 degrees; and
each of the first and second OP-amps is a fully differential OP-amp comprising a differential input terminal and a differential output terminal.

8. A phase mismatch compensation device filtering I-channel and Q-channel analog input signals and outputting I-channel and Q-channel output signals, the complex bandpass filter comprising:
an I-channel phase conversion unit changing the phase of the I-channel output signal using the I-channel and Q-channel analog input signals;
a Q-channel phase conversion unit changing the phase of the Q-channel output signal using the I-channel and Q-channel analog input signals; and
a complex filter unit performing filtering.

9. A phase mismatch compensation device comprising:
a first amplifier unit amplifying in-phase channel analog input signals with a gain and outputting I-channel output signal, and comprising a first OP-amp, a first input unit and a first self-feedback unit, the first input unit transferring the I-channel analog input signal to an input terminal of the first OP-amp, and the first self-feedback unit transferring the I-channel output signal to the input terminal of the first OP-amp;
a second amplifier unit amplifying quadrature-phase channel analog input signals with a gain and outputting Q-channel output signal, and comprising a second OP-amp, a second input unit and a second self-feedback unit, the second input unit transferring the Q-channel analog input signal to an input terminal of the second OP-amp, and the second self-feedback unit transferring the Q-channel output signal to the input terminal of the second OP-amp; and
a phase compensation unit comprising a first compensation unit and a second compensation unit, the first compensation unit transferring the Q-channel analog input signal to the input terminal of the first OP-amp, and the second compensation unit transferring the I-channel analog input signal to the input terminal of the second OP-amp.

10. The phase mismatch compensation device according to claim 9, wherein:
each of the first and second input units and the first and second cross-feedback units comprises a resistor with a predetermined resistance;
each of the first and second self-feedback units comprises a resistor with a predetermined resistance and a capacitor; and
each of the first and second compensation units comprises a variable resistor.

11. The phase mismatch compensation device according to claim 9, wherein:
each of the first and second input units and the first and second cross-feedback units comprises an impedance element with a predetermined impedance;
each of the first and second self-feedback units comprises an impedance element with a predetermined impedance; and
each of the first and second compensation units comprises a variable impedance element.

12. The phase mismatch compensation device according to claim 10, wherein:
the first cross-feedback unit comprises an inverting amplifier converting the phase of the Q-channel output signal into 180 degrees; and
the first compensation unit comprises an inverting amplifier converting the phase of the Q-channel analog input signal into 180 degrees.

13. The phase mismatch compensation device according to claim 11, wherein:
the first cross-feedback unit comprises an inverting amplifier converting the phase of the Q-channel output signal into 180 degrees; and
the first compensation unit comprises an inverting amplifier converting the phase of the Q-channel analog input signal into 180 degrees.

14. The phase mismatch compensation device according to claim 9, wherein:
each of the I-channel input/output signals and the Q-channel input/output signals comprises fully differential signals having a phase difference of 180 degrees; and
each of the first and second OP-amps is a fully differential OP-amp comprising a differential input terminal and a differential output terminal.
